(19) United States
(12) Patent Application Publication
(10) Pub. No.: US 2024/0215113 A1
(43) Pub. Date: Jun. 27, 2024

(54) HEATING APPLIANCE

(71) Applicant: Dyson Technology Limited, Wiltshire (GB)

(72) Inventors: Yuen Kee LEOW, Singapore (SG); Zhiyang PAN, Singapore (SG); Kai WANG, Singapore (SG); Stephen John WOOLAGHAN, Swindon (GB); Kishan Mayur AMRATIA, Bristol (GB); Brian William WEEKS, Bath (GB); Glen Raymond WARDLE, Swindon (GB); Adorjan GAVEL, Gloucester (GB)

(73) Assignee: Dyson Technology Limited, Wiltshire (GB)

(21) Appl. No.: 18/288,721

(22) PCT Filed: Apr. 19, 2022
(86) PCT No.: PCT/GB2022/050982

§ 371 Date: Oct. 27, 2023

(30) Foreign Application Priority Data
Apr. 30, 2021 (GB) 2106252.6

(51) Int. Cl. H05B 1/02; H03K 3/0233; H03K 3/356; H03K 3/3565; H03K 5/1536; H03K 5/24

(52) U.S. Cl. CPC H05B 1/0225; H03K 3/02337; H03K 3/356104; H03K 3/3565; H03K 5/1536; H03K 5/24; H05B 1/0252

(57) ABSTRACT

A method for generating a clock signal from an AC power supply signal includes receiving a reference signal at a first input of a comparator and receiving the AC power supply signal at a second input of the comparator. A clock signal is output by the comparator based on a comparison of the reference signal and the AC power supply signal, such that transitions of the clock signal take place while the reference signal is at a trigger voltage. Following each clock signal transition, the reference signal is changed from the trigger voltage to a hysteresis voltage that reduces a likelihood of the comparator outputting, immediately after each clock signal transition, a spurious transition of the clock signal due to noise on the AC power supply signal. The reference signal is then returned from the hysteresis voltage to the trigger voltage prior to return of the AC power supply signal to a level intended to cause a further clock signal transition at the output of the comparator.

### FIELD OF INVENTION

The present invention relates to an appliance. The invention has initially been developed for a haircare appliance, such as a hair dryer. However, the invention may be implemented in other forms, such as in space heaters and hand-dryers.

### BACKGROUND

Haircare appliances are generally used to treat or style hair, and some haircare appliances may treat or style hair using airflow along with heat. Such haircare appliances are typically held by a user and moved relative to the hair to obtain desired treatment or styling. Other appliances, such as space heaters and hand-dryers, may also output a heated airflow.

### SUMMARY OF INVENTION

According to a first aspect, there is provided a method for generating a clock signal from an AC power supply signal, the method comprising: receiving a reference signal at a first input of a comparator; receiving the AC power supply signal at a second input of the comparator: outputting, from an output of the comparator, a clock signal based on a comparison of the reference signal and the AC power supply signal, such that transitions of the clock signal take place while the reference signal is at a trigger voltage: following each clock signal transition, changing the reference signal from the trigger voltage to a hysteresis voltage that reduces a likelihood of the comparator outputting, immediately after each clock signal transition, a spurious transition of the clock signal due to noise on the AC power supply signal; and returning the reference signal from the hysteresis voltage to the trigger voltage prior to return of the AC power supply signal to a level intended to cause a further clock signal transition at the output of the comparator.

The method may comprise alternating the hysteresis value between: a low voltage following a clock transition caused by a rising portion of the AC power supply signal, the low voltage being lower than an average voltage of the AC power supply signal; and a high voltage following a clock transition caused by a falling portion of the AC power supply signal, the high voltage being higher than the average voltage of the AC power supply signal.

The trigger value may be the average voltage of the AC power supply signal.

The method may comprise generating a phase-locked version of the clock signal based on the clock signal output by the comparator. The phase-locked version of the clock signal may be used to provide a clock during a temporary interruption of the AC power supply signal.

The method may comprise applying a timing offset to the clock signal to at least partially mitigate a delay at least partly caused by the comparator and/or the phase-locking.

According to a second aspect, there is provided a method of driving a heater, comprising: generating a clock signal using the method of the preceding aspect: and driving the heater with heater drive circuit, wherein a timing of drive current supplied by the heater drive circuit to the heater is based on the clock signal.

The heater drive circuit may comprise at least one semiconductor switch or solid state relay, the method comprising generating a drive pattern for the at least one semiconductor switch or solid state relay; wherein the driving the heater with the heater drive current comprises controlling the at least one semiconductor switch or solid state relay in accordance with the drive pattern.

According to a third aspect, there is provided a clock generation circuit for generating a clock signal from an AC power supply signal, the clock generation circuit comprising: a comparator having: a first input for receiving a reference signal: a second input for receiving the AC power supply signal: and an output for outputting a clock signal based on a comparison of the reference signal and the AC power supply signal at the first and second inputs, such that transitions of the clock signal take place while the reference signal is at a trigger voltage. The clock generation circuit comprises a reference signal generator for providing the reference signal to the first input, the reference signal generator being configured to: following each clock signal transition, change the reference signal from the trigger voltage to a hysteresis voltage that reduces a likelihood of the comparator from outputting, immediately after each clock signal transition, a spurious transition of the clock signal due to noise on the AC power supply signal: and return the reference signal from the hysteresis voltage to the trigger voltage prior to return of the AC power supply signal to a level intended to cause a further clock signal transition at the output of the comparator.

The reference signal generator may be configured to alternate the hysteresis value between: a low voltage following a clock transition caused by a rising portion of the AC power supply signal, the low voltage being lower than an average voltage of the AC power supply signal: and a high voltage following a clock transition caused by a falling portion of the AC power supply signal, the high voltage being higher than the average voltage of the AC power supply signal.

The trigger value may be the average voltage of the AC power supply signal.

The clock generation circuit may comprise a phase-locking circuit configured to generate a phase-locked version of the clock signal.

The clock generation circuit may comprise: a first feedback circuit connected between the output and the first input, the first feedback circuit comprising a first capacitance: and a second feedback circuit connected between the output and the first input, the second feedback circuit comprising a second capacitance.

The first feedback circuit may comprise a first resistance in series with the first capacitance; and the second feedback circuit may comprise a second resistance in series with the second capacitance.

The first feedback circuit may comprise a first switch, a first terminal of the first switch being connected to a first voltage, a second terminal of the first switch being connected to the first input, and a control terminal of the first switch being connected to the first capacitance; and the second feedback circuit may comprise a second switch, a first terminal of the second switch being connected to a second voltage, a second terminal of the second switch being connected to the first input, and a control terminal of the first switch being connected to the second capacitance.

According to a fourth aspect, there is provided an apparatus comprising: a heater: a heater drive circuit for driving the heater; and the clock generation circuit according to a preceding aspect, configured for providing the clock signal to the heater drive circuit, such that, when the apparatus is in use, the clock signal controls timing of a drive current supplied by the heater drive circuit to the heater.

The heater drive circuit may comprise: at least one semiconductor switch or solid state relay; and a controller configured to generate a drive pattern for the at least one semiconductor switch or solid state relay: configured such that driving the heater with the heater drive current comprises controlling the at least one semiconductor switch or solid state relay in accordance with the drive pattern.

The apparatus may take the form of a haircare appliance.

The heater may be disposed within an airflow path of the haircare appliance.

According to a fifth aspect, there is provided an electrical apparatus comprising a controller configured to: sample at least one voltage based on an AC mains power supply signal, thereby to generate a sequence of samples: apply a low pass function to a sequence of values, each of the values being based on a magnitude of a sample within the sequence of samples: and estimate a voltage of the AC mains power supply based on an output of the low pass function.

This approach may offer a relatively accurate and resource-light approach to determining a voltage of an AC mains power supply.

The controller may be configured to generate the sequence of values

The low pass function may be a moving average function. The moving average may be a simple moving average function.

The controller may be configured to generate the sequence of values by taking an absolute value of each of the sequence of samples.

The at least one voltage based on the AC mains power supply signal may comprise a live circuit voltage and/or a neutral circuit voltage.

The electrical apparatus may comprise a voltage circuit for generating the live circuit voltage and/or the neutral circuit voltage based on a live and/or neutral circuit. The voltage circuit may be configured to scale down the live circuit voltage and/or the neutral circuit voltage before the sampling.

The at least one voltage based on the AC mains power supply signal may comprise a live circuit voltage and/or a neutral circuit voltage, and the controller may be configured to generate the sequence of values by taking a difference between the sampled live circuit voltage and the sampled neutral circuit voltage. Generating the sequence of values by taking a difference between the sampled live circuit voltage and the sampled neutral circuit voltage, or vice versa, may cancel at least some distortion of the live circuit voltage and neutral circuit voltage caused by a capacitance between the live and neutral circuits.

Estimating the voltage of the AC mains power supply may include applying a correction factor.

Applying the correction factor may comprise multiplying an output of the low pass function by the correction factor.

The controller may comprise an analog to digital converter configured to sample the voltage.

According to a sixth aspect, there is provided a method performed in an electrical apparatus, the method comprising: sampling a voltage of an AC mains power supply to which the haircare device is connected, thereby to generate a sequence of samples: applying a low pass function to a the sequence of values, each value being based on a magnitude of a corresponding at least one sample within the sequence of samples: and estimating a voltage of the AC mains power supply based on an output of the low pass function.

The method may comprise generating the sequence of values.

The low pass function may be a moving average function. The moving average may be a simple moving average function.

Generating the sequence of values may comprise taking an absolute value of each of the sequence of samples.

The at least one voltage based on the AC mains power supply signal may comprise a live circuit voltage and/or a neutral circuit voltage.

The method may comprise scaling down the live circuit voltage and/or the neutral circuit voltage before the sampling.

The method may comprise generating the sequence of values by taking a difference between the sampled live circuit voltage and the sampled neutral circuit voltage. Generating the sequence of values by taking a difference between the sampled live circuit voltage and the sampled neutral circuit voltage may cancel at least some distortion of the live circuit voltage and neutral circuit voltage caused by a capacitance between the live and neutral circuits.

Estimating the voltage of the AC mains power supply may include applying a correction factor. Applying the correction factor may comprise multiplying an output of the low pass function by the correction factor.

According to a seventh aspect, there is provided a heating circuit comprising:
a relay having a relay input, a relay output, and a relay control terminal for controlling opening and closing of a switching circuit between the relay input and the relay output responsive to a relay control signal, the relay input being couplable, in use, to one of a live circuit and a neutral circuit of an AC power supply;
a heating circuit comprising a heater, the heating circuit being coupled to the relay output at a node, and being couplable, in use, to the other of the live circuit and the neutral circuit of the AC power supply; and
a detection circuit for detecting a voltage at the node and outputting a detection signal to a controller based on whether a signal having predetermined characteristics is detected at the node.

This arrangement may provide a safer heating circuit.

The controller may be configured to: set the relay control signal value to an open value, and determine a value of the detection signal: and determine whether the relay is, or may be, in a failed-closed state based on the determined value.

The controller may be configured to set the relay control signal value to a closed value, and determine a value of the detection signal; and determine whether the relay is, or may be, in a failed-open state based on the determined value.

The detection circuit may be configured to detect a train of pulses at the node.

The detection circuit may comprise a voltage clamping Zener diode.

The detection circuit may comprise a voltage divider for reducing a voltage detected at the node.

The detection circuit may comprise a monostable circuit for generating a DC voltage when the train of pulses is detected. An output of the monostable circuit may be coupled to supply the DC voltage to an input of the controller.

The heating circuit may be modulatable, and may comprise a power semiconductor switch in series between the heater and the neutral/live circuit, or between the heater and the relay, the power semiconductor switch having a switch control terminal for receiving a switch control signal to modulate current through the power switch in use.

The heating circuit may comprise a safety circuit configured to prevent the detection circuit from outputting the detection signal indicating that there is an AC voltage at the node, when the AC voltage at the node is a result of the power semiconductor switch being in a failed-closed state.

The safety circuit may receive as an input a neutral signal based on the neutral circuit voltage, the neutral signal preventing the detection circuit from outputting the detection signal indicating that there is an AC voltage at the node, at least when the power semiconductor switch is in a failed-closed state. The safety circuit may include a switch that is controlled by the neutral signal, such that while the neutral signal indicates that the voltage of the neutral would be causing a high voltage at the node, the switch is held closed, thereby to prevent the neutral circuit from causing the detection circuit to output the detection signal indicating that there is an AC voltage at the node, when the AC voltage at the node is a result of the power semiconductor switch being in a failed-closed state.

According to an eighth aspect, there is provided a method of testing a relay in a heating circuit, the heating circuit comprising:
a relay having a relay input, a relay output, and a relay control terminal for controlling opening and closing of a switching circuit between the relay input and the relay output responsive to a relay control signal, the relay input being couplable, in use, to one of a live circuit and a neutral circuit of an AC power supply: and
a heating circuit comprising a heater, the heating circuit being coupled to the relay output at a node, and being couplable, in use, to a neutral circuit of the AC power supply;
the method comprising:
detecting a voltage at the node; and
outputting a detection signal to a controller based on whether a signal having predetermined characteristics is detected at the node.

The method may comprise setting the relay control signal value to an open value, and determining a value of the detection signal; and determining whether the relay is, or may be, in a failed-closed state based on the determined value.

The method may comprise setting the relay control signal value to a closed value, and determining a value of the detection signal: and determining whether the relay is, or may be, in a failed-open state based on the determined value.

The method may comprise rectifying an AC voltage to generate a train of pulses at the node.

The method may comprise generating a DC voltage based on the train of pulses.

The method may comprise supplying the DC voltage to an input of the controller.

The heating circuit may be modulatable, and may comprise a power semiconductor switch in series between the heater and the neutral/live circuit, or between the heater and the relay, the power semiconductor switch having a switch control terminal for receiving a switch control signal, and the method may comprise modulating current through the power semiconductor switch in use, responsive to the switch control signal.

The method may comprise preventing the outputting of a value of the detection signal indicating that there is an AC voltage at the node, when the AC voltage at the node is a result of the power semiconductor switch being in a failed-closed state.

The method may comprise receiving a neutral signal based on the neutral circuit voltage, based on the neutral signal, disabling the detection circuit from outputting the detection signal indicating that there is an AC voltage at the node, at least when the power semiconductor switch is in a failed-closed state.

The method may comprise controlling a switch with the neutral signal, such that while the neutral signal indicates that the voltage of the neutral would be causing a high voltage at the node, the switch is held open, thereby to prevent the neutral circuit from causing the detection circuit to output the detection signal indicating that there is an AC voltage at the node, when the AC voltage at the node is a result of the power semiconductor switch being in a failed-closed state.

All descriptions of signals and control relating to the neutral circuit may be applied to the live circuit and vice versa, with suitable modifications to the circuits, components and/or methods, as will be understood by the skilled person.

Optional features of aspects of the present invention may be equally applied to other aspects of the present invention, where appropriate.

### BRIEF DESCRIPTION OF DRAWINGS

FIG. 1 is a perspective view of an embodiment of a haircare appliance:

FIG. 2 is a schematic view illustrating internal components of the haircare appliance of FIG. 1:

FIG. 3 is a schematic longitudinal section of a heater housing of the haircare appliance of FIGS. 1 and 2:

FIG. 4 shows a Schmitt trigger circuit:

FIG. 5 is a graph showing the behaviour of the Schmitt trigger of FIG. 4:

FIG. 6 shows a method of generating a clock signal, performed by the haircare appliance of FIGS. 1-3:

FIG. 7 shows a circuit for implementing the method of FIG. 6;

FIGS. 8-10 show waveforms generated by the circuit of FIG. 7:

FIGS. 11 and 12 show waveforms generated by a phase locked loop for generating a clock signal, performed by the haircare appliance of FIGS. 1-3:

FIG. 13 shows a circuit for controlling a power TRIAC with a microcontroller unit (MCU), forming part of the haircare appliance of FIGS. 1-3:

FIGS. 14-16 shows a circuit for testing a relay, forming part of the haircare appliance of FIGS. 1-3:

FIG. 17 shows the circuit of FIGS. 14-16, including a safety circuit;

FIG. 18 shows voltage sensing circuit, forming part of the haircare appliance of FIGS. 1-3; and

FIG. 19 shows waveforms related to the voltage sensing circuit of FIG. 18.

### DETAILED DESCRIPTION

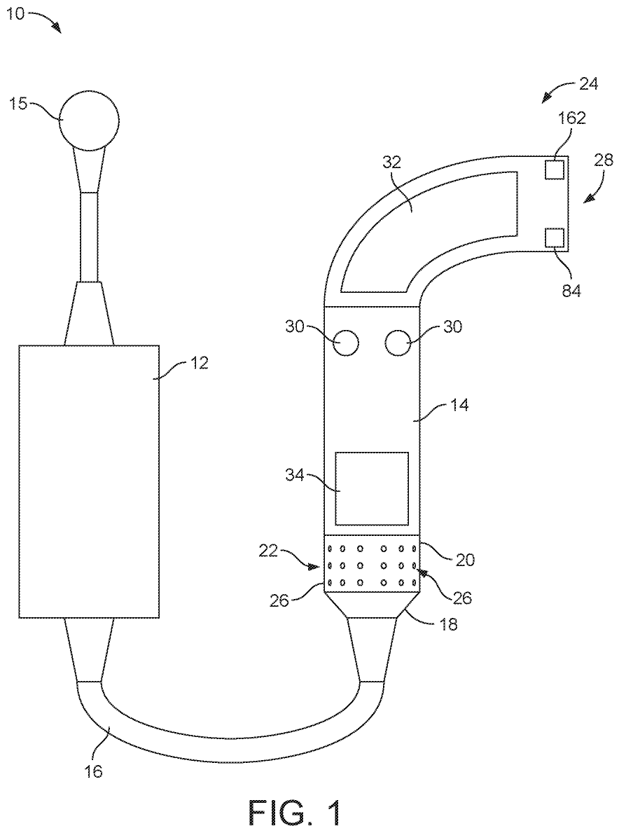

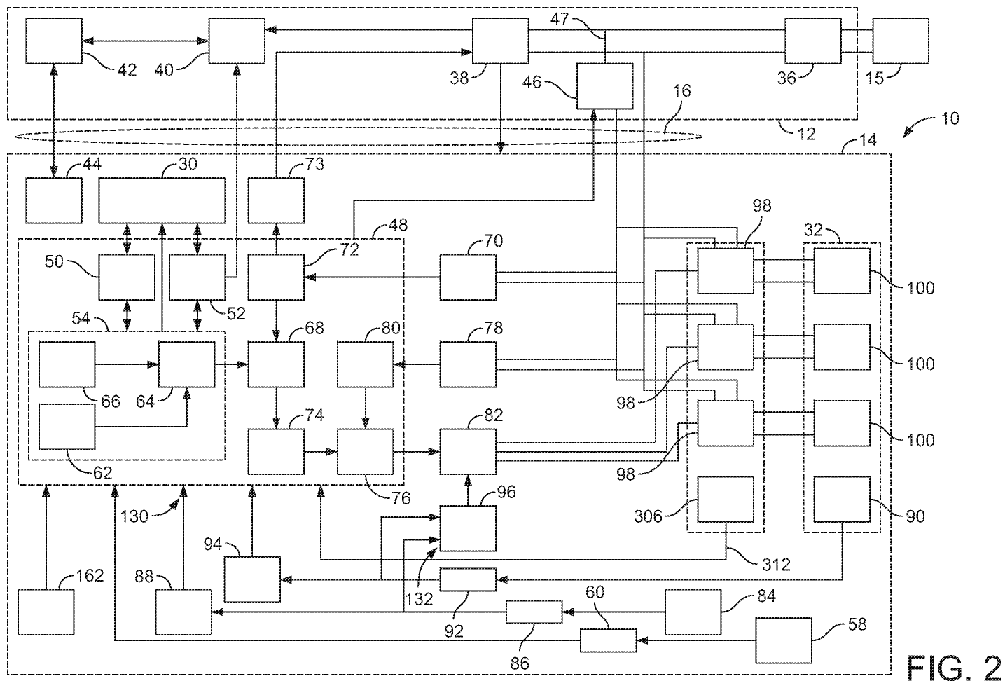

A haircare appliance, generally designated 10, is shown schematically in FIGS. 1 and 2. The haircare appliance 10 in the embodiment of FIGS. 1 and 2 is a hairdryer, although it will be appreciated that some of the teachings discussed herein may be applied to other types of haircare appliance, for example hair straighteners or hair curlers or the like.

The haircare appliance 10 comprises a circuitry housing 12, a heater housing 14, and an electrical cable 16 extending from the circuitry housing 12 to the heater housing 14. The circuitry housing 12 defines an enclosure that houses a number of electronic components as will be described hereinafter, and the electronic components within the circuitry housing 12 are coupled to corresponding electronic components within the heater housing 14 by wires held within the electrical cable 16. Whilst referred to as wires, it will be appreciated that each wire may comprise more than one electrically conducting filament, for example as is the case with a braided wire, with the overall structure of multiple filaments being considered a wire. A power connector 15 in the form of a plug is coupled to the opposite side of the circuitry housing 12 to the electrical cable 16. The power connector 15 is configured to interact with an AC mains power supply, for example via a mains socket (not shown), to provide electrical current to the haircare appliance 10 in use.

The heater housing 14 defines a hollow, generally elongate, handle that is intended to be grasped by a user in use. As seen in FIG. 1, the heater housing 14 comprises a conical end portion 18 and a wall 20 extending upwardly from the conical end portion 18, such that a first end 22 of the heater housing 14 is generally cylindrical in form. The heater housing 14 has a second end 24 distal from the first end 22, and the heater housing 14 is curved such that the second end 24 is angled relative to the first end 22. An air inlet 26 is located at the first end 22 of the heater housing 14 on the wall 20, and takes the form of a plurality of apertures, for example in a mesh-like structure. An air outlet 28 is located at the second end 24, and comprises an aperture through which air may flow in use.

A user interface 30 is formed on the wall 20, and may take the form of a plurality of buttons, a touchscreen, or a combination thereof. User interface 30 allows a user to input various desired settings that are used by the other components of the haircare appliance 10 to control heat and fan settings, and may also provide visual and/or audible feedback, as described in more detail below.

A heater 32 and an airflow generator 34 are disposed within the heater housing 14.

Turning to FIG. 2, the internal components and functional features of the haircare appliance 10 will be described in more detail. The skilled person will appreciate that the components and features are set out in schematic form, and that the relative positions and sizes of those components and features of the actual appliance may vary from what is illustrated in FIG. 2.

Power connector 15 supplies, in use, AC mains power into circuitry housing 12. The AC mains power is supplied to a mains filter 36, which filters the AC mains power. Operation of the mains filter 36 is described in more detail below.

The AC output of the mains filter 36 is supplied to the input of an AC-to-DC converter 38. The AC-to-DC converter 38 converts the incoming AC voltage to DC, outputting various DC voltages as required by different components of the haircare appliance 10, as described in more detail below.

One output of the converter 38 is a DC power supply to a fan motor controller 40. Fan motor controller 40 receives control signals as described in more detail below, and outputs a fan motor drive signal to an electromagnetic compatibility (EMC) filter 42. The EMC filter 42 outputs the filtered fan motor drive signal to a fan motor 44. The EMC filter filters out harmonics generated by the fan motor 44, in use. The fan motor 44 forms part of the airflow generator 34, as described in more detail below.

Fan motor 44 may take the form of, for example, a V9 Dyson Digital Motor by Dyson Technology Limited. The V9 Dyson Digital Motor is a single-phase motor. Use of a single-phase motor may reduce the number of wires required to extend from circuitry housing 12 to heater housing 14 compared to, for example a similar arrangement where a three-phase motor is utilised by the airflow generator 34 within heater housing 14. Alternatively, a three-phase motor may be used to obtain a smaller and/or lighter heater housing 14.

The output of mains filter 36 also supplies the filtered AC mains power to heater housing 14 via electrical cable 16. Circuitry housing 12 also includes a relay 46, for selectively switching live circuit 48 of the AC mains power. Control of relay 46 is described in more detail below.

Several of the features and components of the haircare appliance 10 are implemented in a microcontroller unit (MCU) 48, as described in more detail below. The MCU 48 includes a processor, memory, and other components necessary to implement the features and components described herein. Although the example describes the use of a haircare appliance 10 having a single MCU 48 disposed within heater housing 14, it will be appreciated that the MCU 48 may be located within circuitry housing 12. Alternatively, implementation of the features and components of the haircare appliance 10 may be distributed across two or more processors, located within circuitry housing 12, heater housing 14, or both. Additional supporting circuitry, such as communications and power, are omitted for clarity. An example of a suitable MCU is the ARM Cortex-M0+.

User interface 30 allows a user to set a target temperature 50 and a fan speed 52. Target temperature 50 and fan speed 52 may each be selectable from a relatively small number of options (e.g., high, medium and low settings for each of target temperature 50 and fan speed 52). Alternatively, either or both of the target temperature 50 and fan speed 52 may be selected in a more granular way. For example, target temperature may be chosen as a specific temperature in degrees C. or F, to a resolution of, say, 5, 10 or 20°. Similarly, fan speed 52 may be chosen as a specific airflow, such as in litres per second.

Target temperature 50 and fan speed 52 are stored within MCU 48. They may be stored persistently or reset to default values at each start-up of the haircare appliance 10.

Fan speed 52 is provided as an input to fan motor controller 40 and to a control block 54 within MCU 48, and target temperature 50 is supplied to control block 54, as described in more detail below.

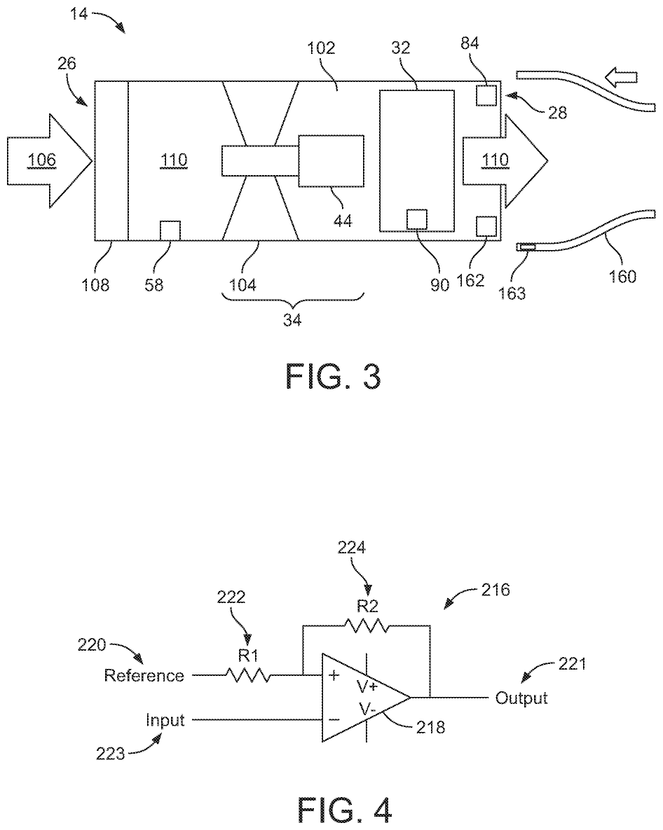

As described in more detail below in relation to FIG. 3, heater housing 14 includes an air pressure sensor in the form of a barometer 58. Barometer 58 provides a raw pressure signal to pressure processing circuitry 60, which includes scaling and filtering circuitry that processes the raw pressure signal before outputting it as a pressure value. Such circuitry is well known to the skilled person and so will not be described in more detail. The pressure value is provided as an input to MCU 48, where it is used as described below. The pressure value may be, for example, the instantaneous pressure value based on the raw pressure signal from barometer 58. Alternatively, the pressure value may be low-pass filtered to reduce the impact of, for example, noise or spurious short-term pressure changes.

As described in more detail below in relation to FIG. 3, heater housing 14 includes an air exit temperature (AET) sensor 84. AET sensor 84 provides a raw temperature signal to AET processing circuitry 86, which includes scaling and filtering circuitry that processes the raw temperature signal before outputting it as a temperature value. Such circuitry is well known to the skilled person and so will not be described in more detail. The temperature value may be, for example, the instantaneous temperature value based on the raw signal from AET sensor 84. Alternatively, the temperature value may be low-pass filtered to reduce the impact of, for example, noise or spurious short-term temperature changes.

The temperature value is provided as an input to an AET buffer 88, as described in more detail below. AET buffer 88 provides a buffered temperature value as an input to MCU 48, where it is used as described in more detail below.

Heater housing 14 includes a heater temperature sensor 90, positioned to sense a temperature of heater 32. Heater temperature sensor 90 provides a raw temperature signal to heater temperature processing circuitry 92, which includes scaling and filtering circuitry that processes the raw temperature signal before outputting it as a temperature value. Such circuitry is well known to the skilled person and so will not be described in more detail. The temperature value is provided as an input to a heater temperature buffer 94, as described in more detail below. Heater temperature buffer 94 provides a buffered temperature value as an input to MCU 48, where it is used as described in more detail below.

Pressure processing block 62 within control block 54 processes the pressure and temperatures value as described in more detail below, and outputs control information to a power controller 64 within control block 54. Target smoothing block 66 processes the target temperature 50 as described in more detail below, and outputs power target information to power controller 64. Based on the received control information and power target information, power controller 64 outputs a power control signal to a current controller 68.

The AC power supply provided from circuitry housing 12 to heater housing 14 via electrical cable 16 is supplied as an input to a voltage sensing circuit 70. Voltage sensing circuit 70 may comprise, for example, an analogue to digital converter for sampling a voltage of the AC power supply and converting it to a numerical value that can be used by MCU 48. The output voltage sensing circuit 70 is provided to an RMS voltage calculator 72, which determines an RMS voltage of the AC power supply, as described in more detail below.

The calculated RMS voltage is provided as an input to current controller 68. The calculated RMS voltage is also provided as an input to a voltage check block 73. Voltage check block 73 determines whether the calculated RMS voltage is above a threshold (or, alternatively, below a threshold, or between two thresholds), and outputs a gate control signal to the converter 38, as described in more detail below.

Current controller 68 uses the RMS voltage and power control signal to determine a desired power output, which may be in the form of an instantaneous or average desired current, power, or combination thereof. The desired output is provided as an input to a TRIAC pattern calculator 74. TRIAC pattern calculator 74 uses the desired output to generate a suitable TRIAC drive pattern. For example, the TRIAC pattern calculator 74 may use a burst-fire control scheme, a phase angle control scheme, or a combination thereof, to generate a TRIAC drive pattern to control current flow to heater elements, as described in more detail below. The TRIAC drive pattern is provided as an input to TRIAC drive signal generator 76.

The AC power supply provided from circuitry housing 12 to heater housing 14 via electrical cable 16 is also supplied as an input to a zero-crossing detection circuit 78. The zero-crossing detection circuit 78 determines zero-crossing points of the AC power supply, as described in more detail below, and provides them as an input to a delay compensation block 80 within MCU 48. The delay compensation block 80 determines a suitable delay compensation value and provides this as an input to TRIAC drive signal calculator 76.

TRIAC drive signal calculator 76 converts the TRIAC drive pattern into suitable TRIAC drive signals and applies appropriate delay compensation, as described in more detail below. The TRIAC drive signals are output from MCU 48 and provided as an input to TRIAC drive circuit 82.

The AET temperature and heater temperature are also provided as inputs to overheat protection circuitry 96. Overheat protection circuitry 96 operates to determine when the AET temperature and/or heater temperature exceed various thresholds, and provides overheat control signals to TRIAC drive circuit 82 so that appropriate action can be taken, as described in more detail below.

TRIAC drive circuit 82 outputs TRIAC drive signals to TRIACs 98, and the TRIACs 98 are also coupled to receive the AC power supply, as described in more detail below. Although three TRIACs are illustrated, the skilled person will appreciate that any suitable number of TRIACs may be driven by the TRIAC drive signals.

Each TRIAC 98 drives a heater element 100 within heater 32. Each heater element 100 may take the form of, for example, a resistive trace on a heat-resistant substrate, such as a resistive wire wound around an insulating scaffold. Alternative types of heater can use a heater track printed onto a polyamide sheet such as Kapton or a ceramic heater coupon having an embedded heater track formed from a trace made from an electrically conductive material such as but not limited to tungsten. In order to dissipate heat from the ceramic heater coupon cooling fins may be provided. Each heater element 100 is exposed to air flowing through an air flow path of the haircare appliance 10, as described in more detail below.

FIG. 3 shows a simplified schematic and partially sectioned view of the heater housing 14 and some of the components it contains. Many of the features and components described in relation to FIGS. 1 and 2, including the bend in heater housing 14, have been omitted for clarity.

FIG. 3 shows schematically an air flow path 102 defined within heater housing 14. Airflow generator 34 comprises the fan motor 44 and an axial impeller 104. Fan motor 44 drives impeller 104 to generate airflow. Air is initially sucked through air inlet 26, as shown by an air-in arrow 106. The air passes through an inlet filter 108, which filters particles such as dust and hair from the air before it passes into the airflow path 102. In use, resistance offered by inlet filter 108 causes a reduced pressure region 110 between inlet filter 108 and impeller 104. Pressure sensor 58 is disposed within this region, to allow sensing of pressure changes as described in more detail below.

Air moves through impeller 104 and past motor 44, cooling motor 44 as it passes. The air is then heated as it passes through heater 32. The temperature of heater 32 is monitored by heater temperature sensor 90, as described in more detail below. Air then passes AET sensor 84, before exiting outlet 28 as shown by an air-out arrow 110.

Haircare appliance 10 may be used with one or more optional detachable accessories, such as a flow-accelerating accessory 160 as shown in FIG. 3. Accessory 160 may be releasably attached at or adjacent air outlet 28 to control the shape, direction and speed, for example, of the airflow. Haircare appliance 10 includes a sensor or scanner, such as ID sensor 162, that allows an attached airflow accessory to be identified.

An attached airflow accessory 160 may be identified in any of a number of ways. For example, the accessory 160 may include an identifier that can be sensed or scanned by corresponding ID sensor 162.

The identifier may take the form of a circuit that can communicate the identifier. For example, the identity can be encoded by an identifier in the form of an RFID or near field communication (NFC) device 163 disposed in or on a portion of the accessory. In that case, ID sensor 162 takes the form of a corresponding RFID/NFC scanner provided on or in the haircare appliance 10.

The identifier may, alternatively or in addition, take the form of a scannable image, that may be printed, embossed, engraved, 3-D-printed, or otherwise disposed in a scannable form onto or into a surface of the airflow accessory 160. The scannable image may take the form of, for example, a QR-code, a barcode, alphanumeric text, or any other suitable form of machine-readable image. The ID sensor 162 takes the form of a corresponding sensor or scanner, located in or on the heater housing 14 (or a main housing, in the event the haircare accessory is not formed of separate circuitry housing 12 and heater housing 14). The ID sensor 162 may operate optically (whether or not in the visible spectrum), ultrasonically, or electromagnetically, or based on any other suitable technology, or combination of such technologies.

The identifier may alternatively, or in addition, take the form of a physical shape or shapes that encode an identifier. For example, one or more raised ribs, lands, fingers, or recessed portions on the accessory can interact with a corresponding tongue, pin, tang, lever, or other physical element that is connected to, for example, a switch on heater housing 14, such as a physical, optical or electromagnetic switch.

The identifier may alternatively, or in addition, take the form of a magnetic or electromagnetic portion that can be sensed by a corresponding magnetic- or electromagnetic-sensitive switch or sensor.

Whatever approach is taken to identifying an attached airflow accessory, in general, installation of the accessory 160 onto the heater housing 14 results in the ID sensor 162 or scanner being positioned adjacent the identifier 163 (or the structure or mechanism by which the identifier is encoded). The scanner or sensor can then sense or scan the identifier value, allowing the haircare appliance 10 to identify the attached accessory 160.

The identifier can be, for example, an index, the haircare appliance 10 having a memory that stores a table mapping each index to information that allows airflow calculations to take into account the attached accessory. For example, the information may comprise a correction factor related to the identified accessory, allowing the airflow calculations to be suitably corrected for the impact of the attached accessory. Alternatively, the identifier may directly encode the information. For example, the identifier may store a number representative of a correction factor related to the accessory.

The identifier can encode multiple bits, representing several potential accessories and/or indices, allowing a correction factor to be used that best corresponds to a particular accessory that is attached. Alternatively, the identifier may effectively encode a single bit of information, allowing the haircare appliance 10 to identify the simple presence or absence of an accessory. This enables a single correction factor to be applied for all accessories, if attached. Although this may be limiting where multiple possible accessories are possible, simple presence/absence detection has the benefit of simplicity and potentially higher reliability.

Turning to zero-crossing detection circuit 78, in electronic circuits involving a comparator, hysteresis may be used to prevent spurious switching caused by electrical noise at one or more inputs of the comparator.

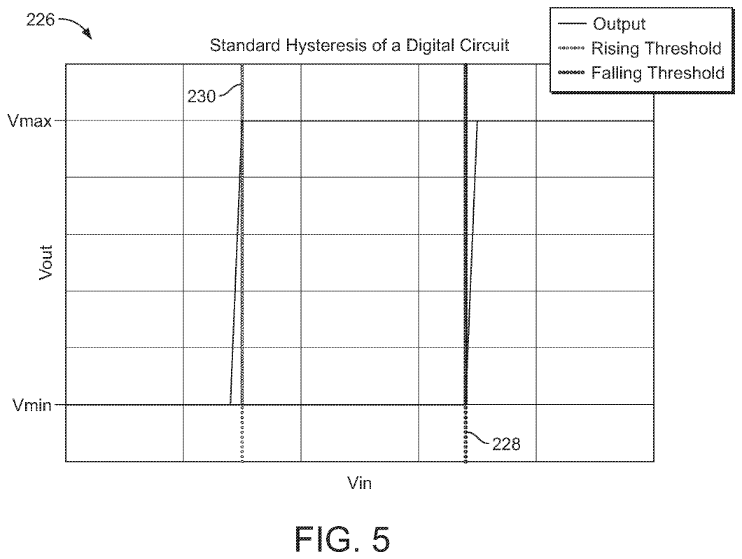

As shown in FIG. 4, one circuit that uses hysteresis is a Schmitt trigger 216. The Schmitt trigger includes a differential amplifier 218. A reference voltage 220 is supplied to the non-inverting input of the amplifier 218 via a first resistor 222. An output 221 of the amplifier 218 is fed back to the non-inverting input of the amplifier 218 via a second resistor 224. An input voltage 223 is provided to the inverting input of amplifier 218.

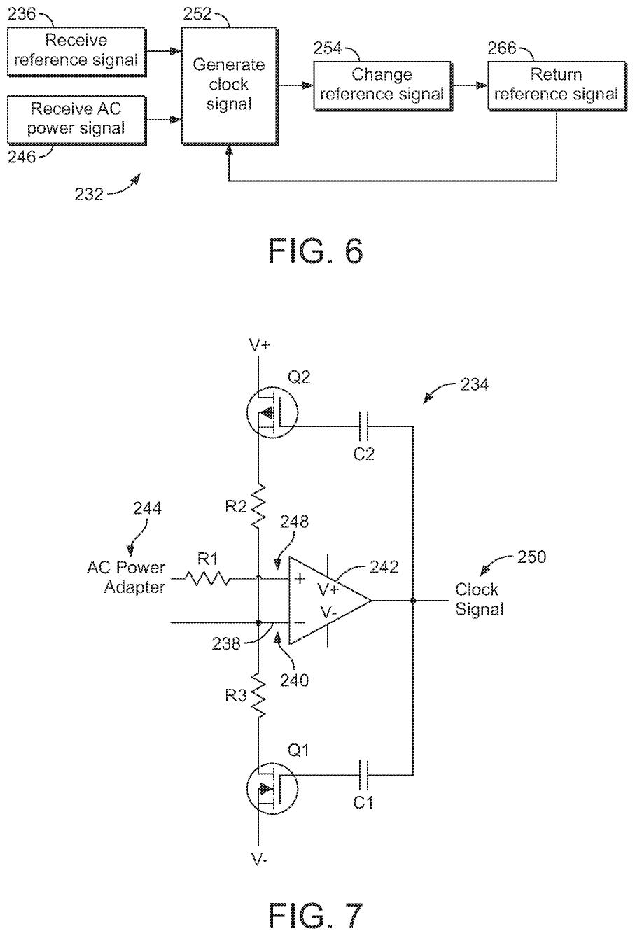

In use, the voltage appearing at the non-inverting input of the amplifier 218 changes depending upon the voltage at the output. A graph 226 showing the relationship between the input voltage and the output voltage is shown in FIG. 5. Starting with the output and input at their minimum levels, the output initially remains at the minimum level Vmin while the input voltage rises. When the input voltage Vin reaches a first threshold 228, the output voltage Vout quickly rises to its maximum voltage Vmax and remains there as the input voltage Vin continues to change. The first threshold 228 is set based on the voltage at the non-inverting input of the differential amplifier 218.

The transition of the output voltage Vout to Vmax causes the first threshold 228 to be replaced by a second threshold 230, based on the change to the voltage at the non-inverting input of differential amplifier 218.

As the input voltage Vin falls, passing the first threshold 228 does not cause the value of Vout to change. Instead, the value of Vout changes when the input voltage Vin reaches the second threshold 230. At that point, the value of Vout drops to Vmin.

The transition of the output voltage Vout to Vmin causes the second threshold 230 to be replaced by the first threshold 228, based on the change to the voltage at the non-inverting input of the differential amplifier 218. The value of the first threshold 228 and the second threshold 230 are selected by the circuit designer to achieve a desired level of noise immunity and circuit performance.

A drawback with using hysteresis is that the use different threshold voltages can exacerbate jitter at the output. This is of increased interest if the signal generated by the changes in levels is to be used for the generation of a timing signal.

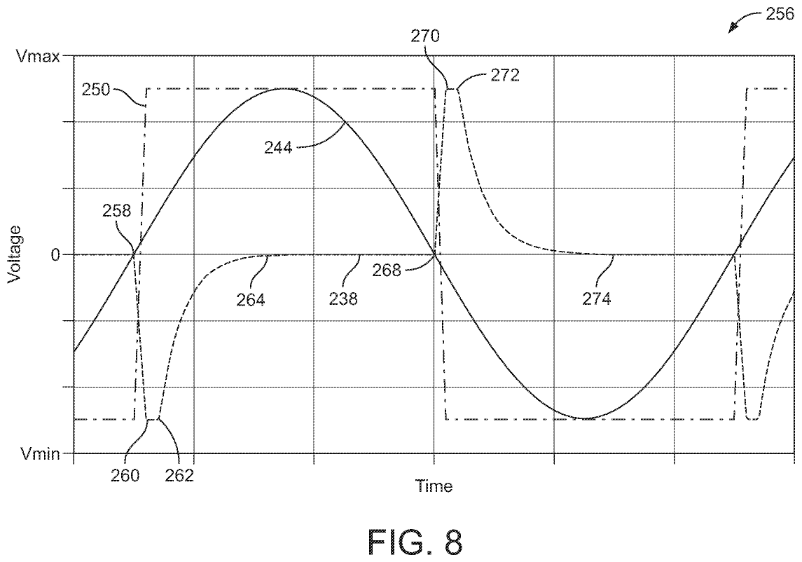

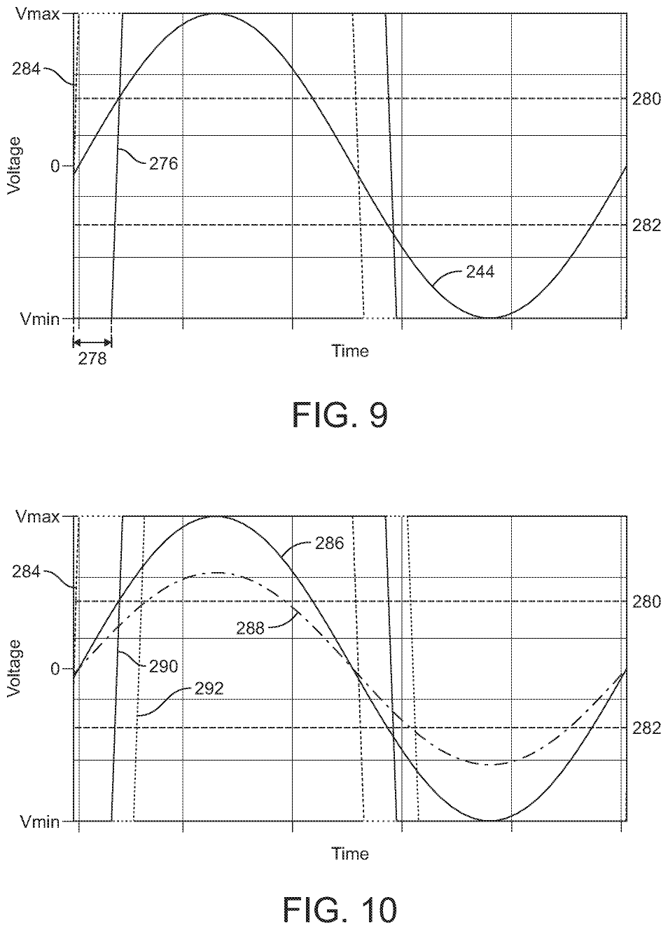

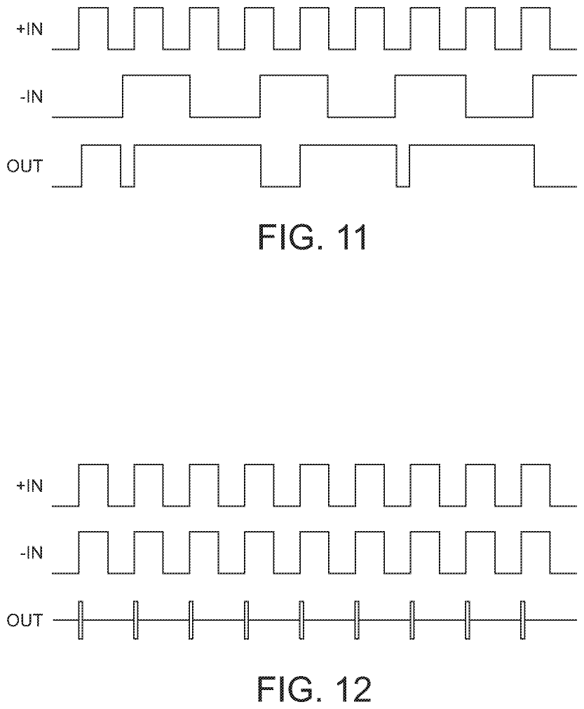

Turning to FIG. 6, there is provided a method 232 for generating a clock signal from an AC power supply signal. In the current example, the AC power supply signal is the AC power supply provided to heater housing 14 over electrical cable 16, as shown in FIG. 2. Method 232 will be described with reference to a hysteresis circuit 234 as shown in FIG. 7, and signal diagram 256 of FIG. 8. However, it will be appreciated that the method may be implemented in many other forms, including analogue and/or digital circuitry, and/or firmware or software.

Method 232 includes receiving 236 a reference signal 238 at a first input 240 of a comparator 242. In this case, first input 240 is an inverting input. Method 232 also includes receiving 246 AC power supply signal 244 at a second input 248 of comparator 242. In this case, second input 248 is a non-inverting input. Reference signal 238 and AC mains power supply signal 244 are updated and received continuously or repeatedly throughout the following method.

Reference signal 238 is initially at a trigger voltage. The trigger voltage may be set at the nominal average voltage of the AC power supply signal being used to generate the clock signal. While the AC power supply may alternate around zero volts, if the MCU 48 is supplied with, say, a 3.3V DC power supply (referenced to 0V), it may be desirable to generate the clock signal based on a version of the AC power supply signal that alternates around 1.65V, with a maximum voltage just below 3.3V and a minimum voltage just above 0V.

The skilled person will appreciate that other trigger, maximum and minimum voltages may be used, depending upon the particular application. Although it may be convenient to have the AC power supply signal have a similar voltage range and DC offset (if any) as the clock signal to be generated, the voltage ranges and offsets may be different in certain applications.

Next, a clock signal 250 is generated 252 based on a comparison of the reference signal 238 and the AC power supply signal 244, such that transitions of the clock signal 250 take place while the reference signal 238 is at the trigger voltage. With reference to FIG. 8, the rising value of the AC power supply signal 244 crosses reference signal 238 at first time 258, causing clock signal 250 transition to a high value (Vmax).

While the clock signal is in transition, reference signal 238 is changed 254 from the trigger voltage to a hysteresis voltage that reduces a likelihood of the comparator 242 outputting, immediately after each clock signal transition, a spurious transition of the clock signal due to noise on the AC power supply signal. With reference to FIG. 8, while clock signal transition 252 is under way, the voltage of reference signal 238 drops to a low voltage Vmin, which it reaches at second time 260, in this case at a similar time to when the clock transition is complete.

Reference signal 238 is maintained at Vmin for a brief period until fourth time 264. The length of the period between second time 260 and third time 262 may be selected based on testing and/or modelling, such that it gives the desired protection from spurious triggers due to noise on the AC power supply signal 244.

Reference signal 238 is then returned 266 from the hysteresis voltage Vmin to the trigger voltage. This return is completed prior to return of the AC power supply signal to a level intended to cause a further clock signal transition at the output of the comparator. With reference to FIG. 8, after third time 262, reference signal 238 returns from the hysteresis voltage Vmin to the trigger voltage of 0V, by fourth time 264. The time by which reference signal 238 is returned to the trigger voltage may be selected based on testing and/or modelling.

Assuming it is intended to generate the clock signal continuously, step 266 returns to step 252, and the process is repeated as required. With reference to FIG. 8, the falling value of the AC power supply signal 244 crosses reference signal 238 at a fifth time 268, causing clock signal 252 to transition to a low value (Vmin). While clock signal transition 252 is under way, the voltage of reference signal 238 rises to a high voltage Vmax, which it reaches at sixth time 270, in this case at a similar time to when the clock transition is complete.

Reference signal 238 is maintained at Vmax for a brief period until a seventh time 272. The length of the period between sixth time 270 and seventh time 272 may again be selected based on testing and/or modelling, such that it gives the desired protection from spurious triggers due to noise on the AC power supply signal 244.

After seventh time 272, reference signal 238 returns from the hysteresis voltage Vmax to the trigger voltage of 0V, by eighth time 274. Again, the time by which reference signal 238 is returned to the trigger voltage may be selected based on testing and/or modelling.

Steps 252, 254 and 266 are then repeated, with the hysteresis values alternating between high and low voltages, depending upon whether the AC power supply voltage is falling or rising when it crosses the trigger voltage.

The skilled person will appreciate that, although FIG. 8 shows the AC power supply signal 244 and hysteresis values covering the same voltage range, this is not a requirement. In some circumstances, the hysteresis values may be greater or less than the corresponding peaks and troughs of the AC power supply signal upon which the clock signal is based. The hysteresis values need only be sufficient to give the required protection from spurious triggering.

The voltages shown in FIG. 8 are simplified for the sake of clarity. The shapes of the various waveforms will vary depending upon the particular application. For example, the return of the reference signal 238 from Vmin and Vmax to 0V are shown as curved lines, to represent a falling voltage in an analog circuit. The actual waveform may take a different shape, especially where a different circuit is used to achieve the same outcome.

Hysteresis circuit 234 will now be described in more detail. Clock signal 250 is fed back to a first capacitor C1 and a second capacitor C2. The other side of capacitor C1 is connected to control a gate of a first MOSFET Q1, and the other side of capacitor C2 is connected to control a gate of a second MOSFET Q2. Q1 is an N-channel MOSFET and Q2 is a P-channel MOSFET.

The source of Q2 is connected to V+(i.e., Vmax in the example given above), and the drain of Q2 is connected to first input 240 through resistor R2. The source of Q1 is connected to V− (i.e., Vmin in the example given above), and the drain of Q2 is connected to first input 240 through resistor R3.

Putting the operation of hysteresis circuit 234 in the context of FIG. 8, when the clock signal 250 transitions to Vmax between first time 258 and second time 260, clock signal 250 rises at the output of comparator 242. The change in voltage is passed by capacitors C1 and C2 to the gates of first MOSFET Q1 and second MOSFET Q2 respectively. The rising voltage turns on the first MOSFET Q1, and has no effect on the second MOSFET Q2 (which is already turned off). The voltage at first input 240 is pulled down to V− (i.e., Vmin) by way of resistor R3.

Because capacitor C1 blocks DC, the voltage at the gate of first MOSFET Q1 falls after the transition of clock signal 250 to Vmax is complete. MOSFET Q1 gradually turns off as the voltage at its gate falls, allowing reference voltage 238 to return to 0V.

When AC power supply voltage 244 subsequently falls past reference signal 238, it triggers transition of clock signal 250 to Vmin between fifth time 268 and sixth time 270. Clock signal 250 falls at the output of comparator 242. The change in voltage is passed by capacitors C1 and C2 to the gates of first MOSFET Q1 and second MOSFET Q2 respectively. The falling voltage turns on the second MOSFET Q2, and has no effect on the first MOSFET Q1 (which is already turned off). The voltage at 240 is pulled up to V+ (i.e., Vmax) by way of resistor R2.

Because capacitor C2 blocks DC, the voltage at the gate of second MOSFET Q2 rises after the transition of clock signal 252 to Vmin is complete. MOSFET Q2 gradually turns off as a voltage at its gate rises, allowing reference voltage 238 return to 0V.

FIG. 9 shows how having a clock transition trigger at 0V and changing the hysteresis value temporarily at each clock transition reduces phase offset as compared with traditional hysteresis. FIG. 9 shows that, in a traditional hysteresis circuit, the clock transition 276 takes place following a delay 278 after the AC power supply voltage passes 0V. This is because upper trigger value 280 and lower trigger value 282 only cause triggering of the clock transition once the AC power supply signal 244 has moved some way beyond 0V.

In contrast, having the clock transition trigger at 0V means that triggering takes place as soon as the AC power supply signal 244 crosses 0V (subject to any propagation delays due to the analog nature of circuitry). The clock transition 284 therefore takes place without significant delay.

FIG. 10 shows how having a clock transition trigger at 0V and changing the hysteresis value temporarily at each clock transition reduces phase variation as a result of the AC mains supply voltage. AC mains supply voltages vary from region to region and, to a much smaller extent, based on proximity of the supply point to the electrical distribution network.

While a fixed phase offset can be handled by allowing for the offset in software or circuitry, the problem is considerably more difficult to address if a single product is designed to be used with different supply voltages, such as 230V supply voltage 286 and 120V supply voltage 288. 230V supply voltage 286 rises faster than 120V supply voltage 288, meaning it reaches the upper trigger value 280 sooner than 120V supply voltage 288. This causes an earlier clock transition 290 as compared with the clock transition 292 of lower 120V supply voltage 288.

In contrast, having the clock transition trigger at 0V results in substantially the same timing of clock transition 284 for both the 230V supply voltage 283 and 120V supply voltage 288, because the 0V transition takes place irrespective of the peak voltages involved.

The clock signal 250 can be used as a basis for timing of TRIAC drive signals output by drive signal generator 76. Optionally, clock signal 250 is passed to delay compensation block 80 before being passed to TRIAC drive signal generator 76. Within delay compensation block 80, the timing of clock signal 250 may be adjusted to take into account delays within the circuitry. Such delays can include, for example, propagation delays between TRIAC drive signal generator 76 and TRIACs 98. Such delays can be determined based on tests and/or modelling, allowing a phase compensation offset to be implemented by delay compensation circuit 80.

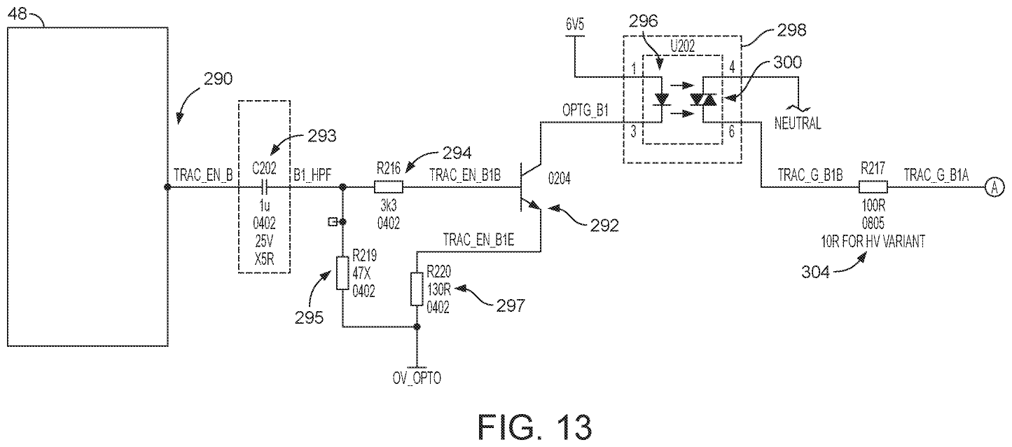

Irrespective of whether delay compensation is employed, optionally, clock signal 250 can be used to drive a phase-locked loop (PLL), which may be implemented as a function in software or as a separate PLL circuit. PLLs are well-understood by the skilled person, and so will not be described in detail. FIG. 11 shows the inputs and output of such a PLL function. +IN is clock signal 250, −IN is an internally generated waveform having a different frequency to clock signal 250 (exaggerated for clarity), and OUT is the output of the PLL function. The OUT waveform of FIG. 11 shows that the PLL has not achieved phase-lock.

The frequency of −IN is gradually adjusted by the PLL function until eventually it matches the +IN signal, as shown in FIG. 12. At that point, the OUT signal shows that the PLL has achieved phase-lock.

Once phase-lock is achieved, a predictable internal waveform is available to trigger events, such as turning on heater 32. This means that it is not necessary to wait until the AC power supply signal causes clock signal 250 to transition, in order to act as a trigger. Instead, the phase-locked internal signal −IN can be used to predict exactly when the next clock signal 250 transition will take place, allowing calculations to be performed and signals to be propagated to the TRIACs 98, while avoiding undue delays. One advantage of accurately knowing the phase of the incoming AC power supply signal is that TRIAC drive signals can be provided to accurately turn the TRIACs 98 on at the crossing point of the AC power supply signal. This reduces the generation of harmonics, and hence interference, that would be caused by turning on the TRIACs 98 at a different point in the waveform.

Slower variances in the frequency of AC power supply signal 244 are handled by the phase-locked loop.

TRIAC drive signal generator 76 receives clock signal 250 and the TRIAC pattern from TRIAC pattern calculator 74, and uses them to generate a TRIAC drive signal at an output pin 290 of MCU 48.

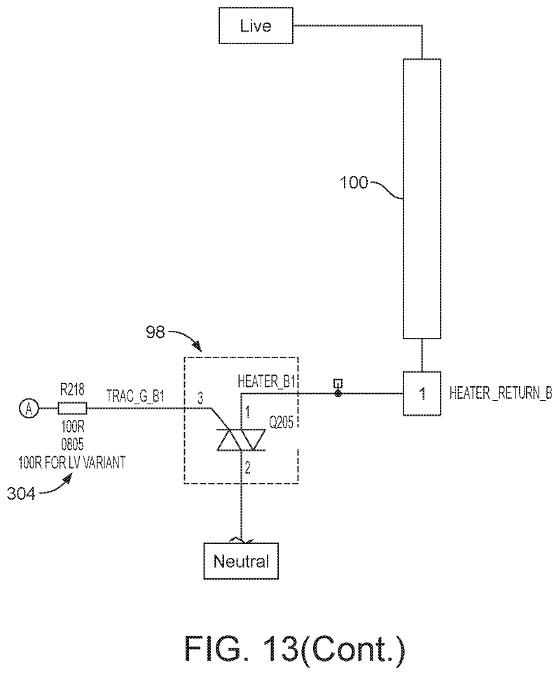

As shown in FIG. 13, the TRIAC drive signal is provided from output pin 290 to the base of a drive transistor 292 via a series-connected capacitor 293 and first resistor 294. A further resistor 295 connects the junction between capacitor 293 and first resistor 294 to 0V. The collector of drive transistor 292 is coupled in series with an LED 296 forming part of an opto-TRIAC 298. The emitter of drive transistor 292 is coupled in series with a current limiting resistor 297. The other terminal of the LED 296 of opto-TRIAC 298 is connected to a power supply (6.5V in this case).

Opto-TRIAC 298 also includes a light-responsive TRIAC 300. One anode of the light-operated TRIAC 300 is coupled to the neutral circuit, and the other anode of light-operated TRIAC 300 is coupled to a gate of power TRIAC 98 (see FIG. 2) via resistors 304. A first anode of power TRIAC 98 is coupled with the neutral circuit and a second anode of power TRIAC 98 is coupled in series with heater trace 100 (see FIG. 2).

When the TRIAC drive signal from output pin 290 is high, drive transistor 292 is turned on, causing current to flow through LED 296 and current limiting resistor 297. Light from LED 296 impinges on light-responsive TRIAC 300, causing it to turn on and connect the neutral circuit to the gate of power TRIAC 98. This causes power TRIAC 98 to start conducting, which in turn allows a drive current to pass through heater trace 100.

When the TRIAC drive signal from output pin 290 is low, drive transistor 292 is turned off, and current does not flow through LED 296. Light-responsive TRIAC 300 therefore remains off, and accordingly no current flows through heater trace 100.

While FIG. 13 only shows the connection of a single opto-TRIAC 298, power TRIAC 98 and heater trace 100, any number of these components may be employed to suit particular implementation requirements. For example, the implementation of FIG. 2 includes three heater traces 100, each of which is driven by a single power TRIAC 98. In other implementations, each power TRIAC 98 can drive one or more heater traces, or each heater trace 100 can be driven by one of more power TRIACs 98, for example.

The optional use of capacitor 293 in series with the base of drive transistor 292 ensures that the power TRIAC 98 is off by default, which may offer additional safety advantages. The capacitor 293 cannot pass DC, and so the TRIAC drive signal is only effective to turn the drive transistor 292 on when it is continuously providing pulses. If output pin 290 remains continuously at a low or high value, the voltage at the base of drive transistor 290 will fall, causing the drive transistor 292 turn off. Accordingly, any software or hardware malfunction that causes a fixed voltage at output pin 290 will not result in spurious activation of heater traces 100.

Although the use of TRIACs is described, any other suitable semiconductor switch or solid state relay may be used, depending upon the implementation. The skilled person will be familiar with any circuitry changes needed in order to allow for devices other than TRIACs to be used as drive components.

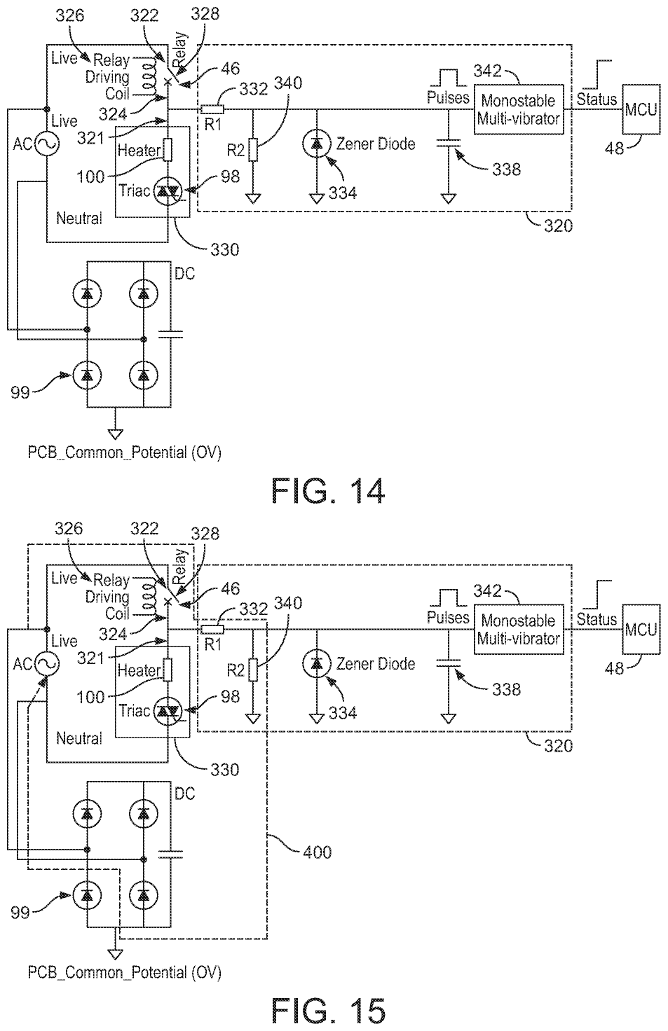

Turning to FIGS. 14-17, operation of relay 46 will now be described in detail. Some components of haircare appliance 10 are omitted for clarity, and heater circuitry housing 12 and heater housing 14 are not shown.

Relay 46 operates to selectively connect and disconnect the AC power supply between circuitry housing 12 and heater housing 14. The AC power supply is used within heater housing 14, at least in the implementation of FIG. 2, by voltage sensing circuit 70, zero-crossing detection circuit 78 and TRIACs 98. However, the focus of the following description of relay 46 is the connection of the AC power supply to TRIACs 98.

A common failure mode of relays, such as relay 46, is to fail closed. For example, a mechanical relay may weld itself shut due to high heat and/or arcing, resulting in a permanently closed circuit. This may present a danger, especially if it is intended to use the relay to cut power in the event of malfunction of a component.

Operation of a relay, such as relay 46, may be tested before and during operation of an appliance such as haircare appliance 10. For example, with reference to FIG. 14, a detection circuit 320 is used in conjunction with MCU 48 to test operation of relay 46. Relay 46 has a relay input 322 connected to the live circuit of the AC power supply, a relay output 324 connected to a modulatable heating circuit 330, a control terminal in the form of relay driving coil 326, and a switching circuit in the form of switch 328 between relay input 322 and relay output 324. Relay driving coil 326 is responsive to a relay control signal output by MCU 48, although the wiring and circuitry between relay 46 and MCU 48 for transmitting the relay control signal is omitted for clarity. The relay control signal controls whether switch 328 is open or closed.

Although the circuits of FIGS. 14-17 show various connections to the live and neutral circuits, the skilled person will appreciate that similar functionality may be achieved by swapping the connections to the neutral/live circuits, with suitable modifications as will be understood by the skilled person.

Modulatable heating circuit 330 is provided in series between relay output 324 and the neutral circuit of the AC power supply. Heating circuit 330 comprises heater trace 100 and a power semiconductor switch in the form of TRIAC 98. For clarity, only a single heater trace 100 and TRIAC 98 are shown. It will be appreciated that relay 46 may control any number of series and/or parallel connected heating circuits 330, such as the three parallel-connected pairs of TRIAC 98 and heater trace 100 shown in FIG. 2.

A power semiconductor switch in the form of TRIAC 98 is optional, and a testing method and circuit for relay 46 may be implemented even when no such power semiconductor switch is included.

A bridge rectifier 99 (forming part of AC to DC converter 38 of FIG. 2) is configured to generate a DC voltage based on the AC power supply voltage.

Detection circuit 320 is connected to a node 321 at the junction between relay outlet 324 and heating circuit 330. Detection circuit 320 comprises a series-connected resistor 332, and a Zener diode 334, capacitor 338 (for noise filtration) and a resistor 340 connected between the output of resistor 332 and 0V. A monostable multi-vibrator 342 is also coupled to the output of resistor 332. The output of monostable multi-vibrator 342 is connected to an input of MCU 48. Resistors 332 and 340 form a voltage divider that reduces the voltage supplied via node 321. Zener diode 334 has a reverse voltage selected to clamp any incoming voltage below a level that could damage multi-vibrator 342.

In use, detection circuit 320 detects a voltage at the node 321, and outputs a detection signal to MCU 48 based on whether a voltage signal having particular characteristics is detected at node 321. As shown in FIG. 15, when relay 46 is closed (whether due to being failed closed or controlled to be closed by MCU 48), the output of the live circuit of the AC power supply circuit generates a half-wave rectified signal at node 321 with respect to 0V. A first current path 400 is followed from live through resistor 332 and resistor 340 to 0V, and then back to neutral via bridge rectifier 99.

As will be appreciated by the skilled person, when TRIAC 98 is off, only the live will generate a signal at 321, and therefore the voltage at 321 is a half wave rectified signal based on the AC power supply. After being reduced in magnitude via the voltage divider formed by resistors 332 and 340, this half wave rectified signal appears as a series of pulses at the input of monostable multi-vibrator 342. Monostable multi-vibrator 342 is triggered by each pulse to output a pulse to the input of MCU 48. The length of the pulse generated by monostable multi-vibrator 342 is selected to be longer than the expected period between pulses at the input of the monostable multi-vibrator 342. As a result, as long as monostable multi-vibrator 342 continues to receive pulses at its input, it will output a continuous “high” signal. MCU 48 detects this “high” signal from monostable multi-vibrator 342, and concludes that an AC voltage is present at node 321.

In use, testing of relay 46 starts by MCU 48 setting the relay control signal value to an open value. This may be performed when haircare appliance 10 is initially connected to the AC power supply, turned on by a user, or wakes from a standby more, for example. If relay 46 is operating correctly, setting the relay control signal value to an open value will cause relay 46 to open, as shown in FIG. 14. This prevents the generation of pulses at node 321. As a result, detection circuit 320 will not generate a “high” output. From this, MCU 48 will conclude that there is no train of pulses at node 321, and hence confirm that relay 46 is open.

Optionally, MCU 48 can then set the relay control signal value to a closed value. This may be performed after the relay 46 was set to an open value and tested, as described in the preceding paragraph. If relay 46 is operating correctly, setting the relay control signal value to a closed value will cause relay 46 to close, as shown in FIG. 15. This allows generation of the train of pulses at node 321, causing detection circuit 320 to generate a “high” signal as described above. From this, MCU 48 can conclude that the train of pulses is present at node 321, and hence confirm that relay 46 is closed.

Although detection circuit 320 offers improved safety, one potential difficulty that may arise is the interaction of heating circuit 330. In particular, a common failure mode for TRIACs, such as TRIAC 98, is to fail in a closed state (i.e., effectively a short circuit). With such a failure, a second current path 344 is established from the neutral circuit, through heater trace 100, resistor 332, resistor 340, and bridge rectifier 99 and back to live, as shown in FIG. 16. This causes a train of pulses to appear at node 321, which can result in testing circuit 320 outputting a “high” signal to MCU 48. This “high” signal will be interpreted as relay 46 being closed, even when it is open as shown in FIG. 16. It is accordingly not possible for MCU 48 to determine whether the “high” signal is a result of relay 46 failing closed.

One way of allowing for testing of relay 46 even if TRIAC 98 fails closed is to prevent outputting of a “high” signal from monostable multi-vibrator 342 when a suitable signal exists at node 321 as a result of the TRIAC 98 being in a failed-closed state. This may be achieved by using the voltage of the neutral circuit to control a safety circuit, such that the safety circuit effectively disables the outputting of a “high” signal by monostable multi-vibrator 342.

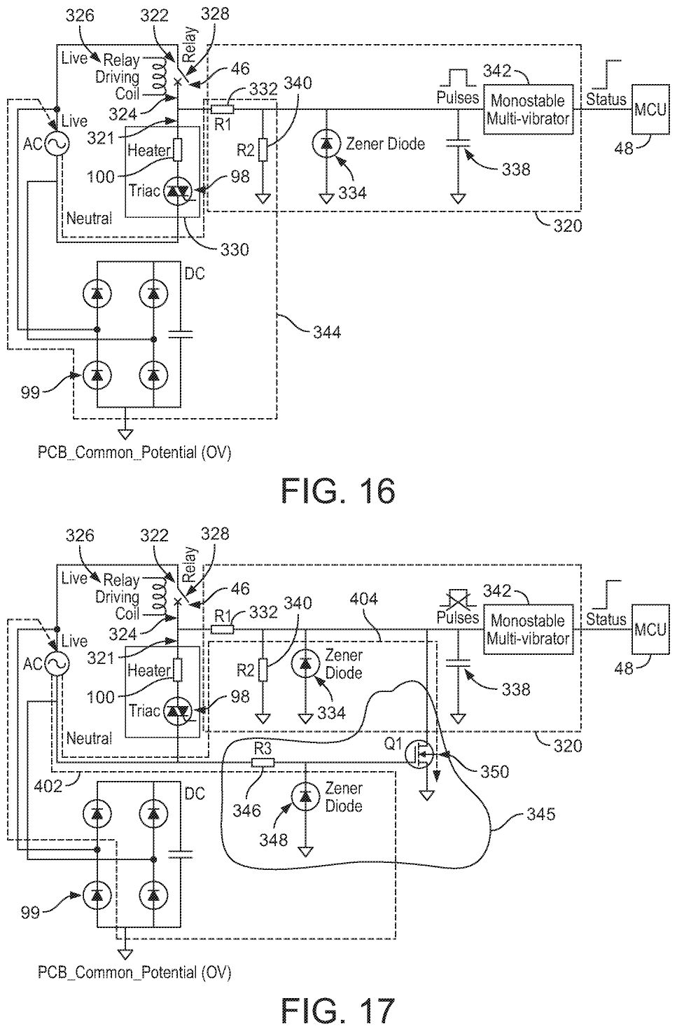

FIG. 17 shows one way in which such a safety circuit 345 may be implemented. Safety circuit 345 accepts as an input the voltage from the neutral circuit. Safety circuit 345 includes a series-connected resistor 346, and a Zener diode 348 connected to 0V. The junction between resistor 346 and Zener diode 348 is coupled to a gate of a switch, the switch in this case taking the form of an N-channel MOSFET 350. The drain of MOSFET 350 is connected to the junction between resistor 332 and Zener diode 334, and the source of MOSFET 350 is connected to 0V.

In use, when relay 46 is open and TRIAC 98 fails closed, the input to safety circuit 345 is a half-wave rectified signal 402 from the neutral circuit. This half-wave rectified signal at the gate of MOSFET 350 causes the MOSFET 350 turn on whenever its voltage is above the turn-on voltage of MOSFET 350. When MOSFET 350 is turned on, the junction between resistor 332 and Zener diode 334 is pulled down 404 to 0V via MOSFET 350. This prevents a voltage at node 321 from causing monostable multi-vibrator 342 to output a “high” signal. As a result, MCU 48 will not conclude that relay 46 (supplied with a relay-open signal) is closed as a result of a spurious signal caused by TRIAC 98 failing closed.

MCU 48 may test operation of the relay in both the open and closed states, as described above. In addition, when haircare appliance is in use (i.e., relay 46 receives “relay closed” signal from MCU), MCU can periodically check whether the relay is, in fact, closed. Further, MCU can check whether the relay is, in fact open, at any time when the relay signal changes to “relay open”. This can happen, for example, immediately after the appliance goes into a standby mode.

As an example, the following is a sequence that can be performed under the coordination of MCU 48:
1. Turn relay 46 off (relay should be open).
2. Check that relay 46 is open, as described above.
3. Turn relay 46 on (relay should close).
4. Check that relay 46 is closed, as described above.
5. Haircare appliance 10 confirmed ready to use.
6. User presses “on” button, causing fan motor 44 and heater 32 to operate in accordance with current settings.
7. Check periodically that relay 46 is closed, as described above.
8. User presses “off” button, causing fan motor 44 and heater 32 to turn off.
9. After a period of inactivity (one minute, for example), turn relay 46 off (to meet standby power requirement).
10. Check that relay 46 is open, as described above.
11. User presses “on” button.
12. Turn relay 46 on (relay should close).
13. Check that relay 46 is closed, as described above.
14. Turn motor 44 and heater 32 on.

If at any time a relay check fails, haircare appliance 10 is shut down for safety. This involves at least cutting power to TRIACs 98, but can also involve full shut-down of the haircare appliance 10.

In step 9 above, relay 46 is only turned off after a period of inactivity, rather than immediately upon the user pressing the “off” button. This avoids excessive actuation of relay 46, since users will often turn the haircare appliance back on shortly after it is turned off. Keeping relay 46 closed for a period will reduce the number of cycles experienced by relay 46 over the long term, thereby increasing the relay's longevity.

In addition, turning relay 46 off only after a period inactivity allows action to be taken in the event TRIAC 98 has failed closed. If TRIAC 98 fails closed, the product can appear to the user to operate normally, despite the danger of the failed TRIAC 98. During the period where relay 46 is deliberately left in the closed state after the user turns haircare appliance 10 off, a failed-closed TRIAC 98 will cause heater 32 to remain fully on while the fan motor 44 is not turning, which will quickly trigger the thermal protection system. The thermal protection system will open relay 46, cutting power to heater 32.

Operation of voltage sensing circuit 70 and RMS voltage calculator 72 will now be described with reference FIGS. 2, 18 and 19. While the following description assumes a class-2 appliance that is not connected to an external ground, the skilled person will appreciate that a device using a grounded power supply can implement the described RMS voltage calculation method and apparatus, with suitable modifications that will be apparent to the skilled person.

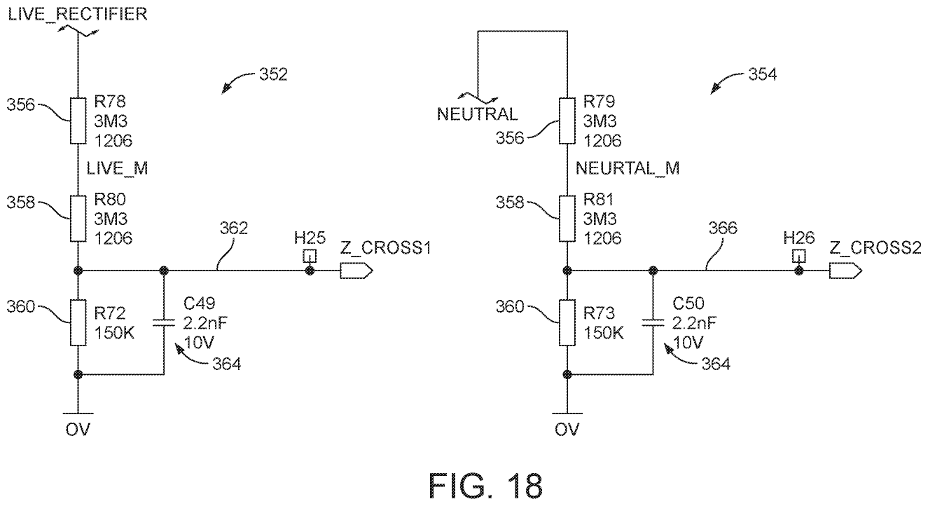

FIG. 18 shows voltage sensing circuit 70. Voltage sensing circuit 70 is connected to the live and neutral circuits provided to heater housing 14 via electrical cable 16, as described above. Voltage sensing circuit 70 includes a live sensing circuit 352 and a neutral sensing circuit 354. Live sensing circuit 352 comprises a voltage divider comprising a first resistor 356, a second resistor 358, and a third resistor 360, serially connected between the live circuit and 0V. The voltage divider has a live output 362 at the junction between second resistor 358 and third resistor 360. A capacitor 364 is connected between live output 362 and 0V. The function of live sensing circuit 352 is to provide a scaled-down (i.e., lower voltage) version of the signal on the live circuit.

Neutral sensing circuit 354 has the same components as live sensing circuit 352, but instead is connected between the neutral circuit and 0V. Neutral sensing circuit 354 uses the same reference signs as those in live sensing circuit 352 where appropriate. However, instead of live output 362, neutral sensing circuit 354 has a neutral output 366. The function of neutral sensing circuit 354 is to provide a scaled-down (i.e., low-voltage) version of the signal on the neutral circuit.

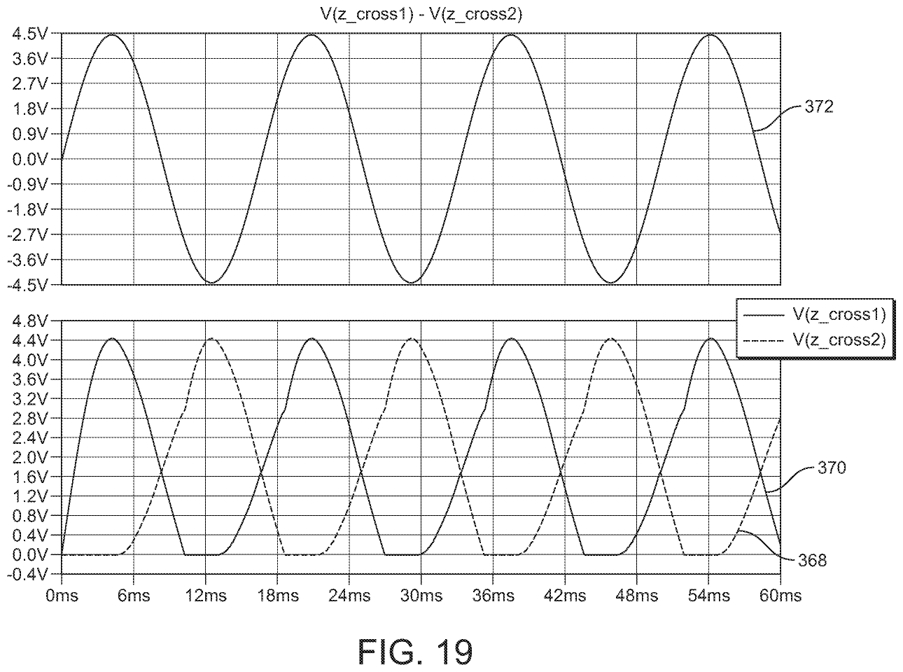

FIG. 19 shows a neutral circuit waveform 368 corresponding to neutral output 366 and live circuit waveform 370 corresponding to live output 362. It will be noted that the waveforms include some distortion due to the effects of filtering capacitors between live/neutral and 0V to filter common-mode noise. The live circuit waveform 370 has a positive peak in phase with the positive peak of the AC power supply signal, while neutral circuit waveform 368 has a positive peak 180° out of phase with the positive peak of the AC power supply signal.

Live output 362 and neutral output 364 are provided as inputs to MCU 48. An analogue to digital converter (not shown) within MCU 48 samples the voltage of the AC mains power supply by sampling the live output 362 (i.e., live circuit waveform 370) and neutral output 364 (i.e., neutral circuit waveform 368), thereby to generate a sequence of samples. In this case, the sequence of samples includes samples relates to the live output 362 and neutral output 364.

Based on the sequence of samples, a sequence of values is generated if required, each of the values being based on a magnitude of at least one sample from the sequence of samples.

In the example shown in FIG. 19, it will be noted that there is some distortion in the live circuit waveform 370 and neutral circuit waveform 368. This distortion arises due to capacitance caused by noise-filtering capacitors between the live/neutral circuits and 0V. The distortion is common-mode, and so can largely be cancelled by taking a difference between the live circuit waveform 370 and neutral circuit waveform 368, the result of which is summed waveform 372. Despite the apparent distortion of live circuit waveform 370 and neutral circuit waveform 368, summed waveform 372 closely resembles the sinewave of the input AC power supply signal.

In this case, MCU 48 generates the sequence of values by calculating a difference between neutral circuit waveform 368 and live circuit waveform 370 at each sampling point of the two waveforms, and then taking an absolute value of the difference. Accordingly, each value in the sequence of values is based on a magnitude of a corresponding sample within the sequence of samples.

Next, a low pass function in the form of a moving window function is applied to the sequence of values. For example, a simple moving average may be applied to the sequence of values. The length of the moving average may be selected to suit the circumstances, but may be several tens or hundreds of samples long.

Low pass function may take the form of any type of moving average, averaging function, or other low-pass filter function suitable to the circumstances.

A voltage of the AC mains power supply may then be estimated, based on an output of the moving window function. For example, the voltage may be estimated based on a mapping between potential outputs of the moving window function and AC mains power supply voltages. If necessary, MCU 48 may apply a correction factor to the output of the moving window function.

Alternatively, the sequence of values may take the form of the sequence of samples, or a subset thereof. For example, live circuit waveform 370 and/or neutral circuit waveform 368 may be sampled, and a moving window function applied directly to those samples. Where applied to just live circuit waveform 370 or neutral circuit waveform 368, a correction factor or mapping can be applied to take into account the fact that the waveform will be around 0V for about half of the time (i.e., between positive excursions).

Where both live circuit waveform 370 and neutral circuit waveform 368 are sampled, their values may be added to generate the sequence of values, or moving window function may be applied to both waveforms separately, and the result averaged.

The sensed voltages generated by voltage sensing circuit 70 can also be used as the inputs for operation of the zero crossing functionality described above.

Although not shown in FIG. 2, circuitry housing 12 can also include a voltage sensing circuit similar to voltage sensing circuit 70, and a further microprocessor, for sensing AC mains supply voltage at the circuitry housing. The sensed voltage can be used, for example, to prevent the haircare appliance from turning on if the voltage is outside an acceptable range. Alternatively, or in addition, the voltage can be monitored for temporary power loss, such as in a brown-out or similar situation. If, in use, the voltage drops below a critical level for more than some predetermined period, operation of the haircare appliance 10 may be halted for safety. An example period would be 20 ms, although other periods may be selected based on circumstances.

More generally, the skilled person will appreciate that there may be a different distribution of components between circuitry housing 12 and heater housing 14 than that shown. Optionally, circuitry housing 12 can incorporate power connector (i.e., plug) 15, such that circuitry housing 12 can be directly plugged into a power socket. Alternatively, all of the components may be disposed within a heater housing, without the use of a separate circuitry housing such as circuitry housing 12.

While haircare appliance 10 has been described as a hairdryer, it will be appreciated that many of the teachings discussed herein may be applied to other types of haircare appliance, such as hair straighteners, hair curlers, and the like, for example. Additionally, the invention can be applied to other appliances that generate a heated airflow, such as space heaters and hand-dryers.

1. A method for generating a clock signal from an AC power supply signal, the method comprising:
receiving a reference signal at a first input of a comparator;
receiving the AC power supply signal at a second input of the comparator;
outputting, from an output of the comparator, a clock signal based on a comparison of the reference signal and the AC power supply signal, such that transitions of the clock signal take place while the reference signal is at a trigger voltage;
following each clock signal transition, changing the reference signal from the trigger voltage to a hysteresis voltage that reduces a likelihood of the comparator outputting, immediately after each clock signal transition, a spurious transition of the clock signal due to noise on the AC power supply signal; and
returning the reference signal from the hysteresis voltage to the trigger voltage prior to return of the AC power supply signal to a level intended to cause a further clock signal transition at the output of the comparator.

2. The method of claim 1, comprising alternating the hysteresis value between:
a low voltage following a clock transition caused by a rising portion of the AC power supply signal, the low voltage being lower than an average voltage of the AC power supply signal; and
a high voltage following a clock transition caused by a falling portion of the AC power supply signal, the high voltage being higher than the average voltage of the AC power supply signal.

3. The method of claim 1, wherein the trigger value is the average voltage of the AC power supply signal.

4. The method of claim 1, comprising generating a phase-locked version of the clock signal based on the clock signal output by the comparator.

5. The method of claim 1, comprising applying a timing offset to the clock signal to at least partially mitigate a delay at least partly caused by the comparator and/or the phase-locking.

6. A method of driving a heater, comprising:
generating a clock signal using the method of claim 1; and
driving the heater with heater drive circuit, wherein a timing of drive current supplied by the heater drive circuit to the heater is based on the clock signal.

7. The method of claim 6, wherein the heater drive circuit comprises at least one semiconductor switch or solid state relay, the method comprising generating a drive pattern for the at least one semiconductor switch or solid state relay;
wherein the driving the heater with the heater drive current comprises controlling the at least one semiconductor switch or solid state relay in accordance with the drive pattern.

8. A clock generation circuit for generating a clock signal from an AC power supply signal, the clock generation circuit comprising:
a comparator having:
a first input for receiving a reference signal;
a second input for receiving the AC power supply signal; and
an output for outputting a clock signal based on a comparison of the reference signal and the AC power supply signal at the first and second inputs, such that transitions of the clock signal take place while the reference signal is at a trigger voltage;
a reference signal generator for providing the reference signal to the first input, the reference signal generator being configured to:
following each clock signal transition, change the reference signal from the trigger voltage to a hysteresis voltage that reduces a likelihood of the comparator from outputting, immediately after each clock signal transition, a spurious transition of the clock signal due to noise on the AC power supply signal; and
return the reference signal from the hysteresis voltage to the trigger voltage prior to return of the AC power supply signal to a level intended to cause a further clock signal transition at the output of the comparator.

9. The clock generation circuit of claim 8, wherein the reference signal generator is configured to alternate the hysteresis value between:
a low voltage following a clock transition caused by a rising portion of the AC power supply signal, the low voltage being lower than an average voltage of the AC power supply signal; and
a high voltage following a clock transition caused by a falling portion of the AC power supply signal, the high voltage being higher than the average voltage of the AC power supply signal.

10. The clock generation circuit of claim 8, wherein the trigger value is the average voltage of the AC power supply signal.

11. The clock generation circuit of claim 8, comprising a phase-locking circuit configured to generate a phase-locked version of the clock signal.

12. The clock generation circuit of claim 8, comprising:
a first feedback circuit connected between the output and the first input, the first feedback circuit comprising a first capacitance; and
a second feedback circuit connected between the output and the first input, the second feedback circuit comprising a second capacitance.

13. The clock generation circuit of claim 12, wherein:
the first feedback circuit comprises a first resistance in series with the first capacitance; and
the second feedback circuit comprises a second resistance in series with the second capacitance.

14. The clock generation circuit of claim 12, wherein:
the first feedback circuit comprises a first switch, a first terminal of the first switch being connected to a first voltage, a second terminal of the first switch being connected to the first input, and a control terminal of the first switch being connected to the first capacitance; and
the second feedback circuit comprises a second switch, a first terminal of the second switch being connected to a second voltage, a second terminal of the second switch being connected to the first input, and a control terminal of the first switch being connected to the second capacitance.

15. An apparatus comprising:
a heater;
a heater drive circuit for driving the heater; and
the clock generation circuit of claim 8, configured for providing the clock signal to the heater drive circuit, such that, when the apparatus is in use, the clock signal controls timing of a drive current supplied by the heater drive circuit to the heater.

16. An electrical apparatus comprising a controller configured to:
sample at least one voltage based on an AC mains power supply signal, thereby to generate a sequence of samples;
apply a low pass function to a sequence of values, each of the values being based on a magnitude of a sample within the sequence of samples; and
estimate a voltage of the AC mains power supply based on an output of the low pass function.

17. A method performed in an electrical apparatus, the method comprising:
sampling a voltage of an AC mains power supply to which the electrical apparatus is connected, thereby to generate a sequence of samples;
applying a low pass function to a sequence of values, each value being based on a magnitude of a corresponding at least one sample within the sequence of samples; and
estimating a voltage of the AC mains power supply based on an output of the low pass function.

18. A heating circuit comprising:
a relay having a relay input, a relay output, and a relay control terminal for controlling opening and closing of a switching circuit between the relay input and the relay output responsive to a relay control signal, the relay input being couplable, in use, to one of a live circuit and a neutral circuit of an AC power supply;
a heating circuit comprising a heater, the heating circuit being coupled to the relay output at a node, and being couplable, in use, to the other of the live circuit and the neutral circuit of the AC power supply; and
a detection circuit for detecting a voltage at the node and outputting a detection signal to a controller based on whether a signal having predetermined characteristics is detected at the node.

19. A method of testing a relay in a heating circuit, the heating circuit comprising:
a relay having a relay input, a relay output, and a relay control terminal for controlling opening and closing of a switching circuit between the relay input and the relay output responsive to a relay control signal, the relay input being couplable, in use, to one of a live circuit and a neutral circuit of an AC power supply; and
a heating circuit comprising a heater, the heating circuit being coupled to the relay output at a node, and being couplable, in use, to a neutral circuit of the AC power supply;
the method comprising:
detecting a voltage at the node; and
outputting a detection signal to a controller based on whether a signal having predetermined characteristics is detected at the node.
